(19) United States
(12) Patent Application Publication
(10) Pub. No.: US 2026/0293746 A1
(43) Pub. Date: Sep. 24, 2026

(54) SEMICONDUCTOR DEVICE AND MANUFACTURING METHOD OF SEMICONDUCTOR DEVICE

(71) Applicants: DENSO CORPORATION, Kariya-city (JP); TOYOTA JIDOSHA KABUSHIKI KAISHA, Toyota-shi (JP); MIRISE Technologies Corporation, Nisshin-shi (JP)

(72) Inventor: Tomotaka ARIGA, Nisshin-shi (JP)

(21) Appl. No.: 19/544,342

(22) Filed: Feb. 19, 2026

(30) Foreign Application Priority Data
Mar. 21, 2025 (JP) 2025-047235

(51) Int. Cl. H10W 72/90; H10W 72/00; H10W 74/10

(52) U.S. Cl. CPC H10W 72/952; H10W 72/01938; H10W 72/923; H10W 72/934; H10W 74/137

(57) ABSTRACT

A semiconductor device includes an electrode. The electrode includes a copper electrode layer. The copper electrode layer contains an element that, when combined with hydrogen, forms a compound with a vapor pressure higher than atmospheric pressure. The element may be fluorine or chlorine. A concentration of the element in the copper electrode layer may be 1×10¹⁶ atoms/cm³ or more.

### CROSS REFERENCE TO RELATED APPLICATION

The present application claims the benefit of priority from Japanese Patent Application No. 2025-047235 filed on March 21, 2025. The entire disclosure of the above application is incorporated herein by reference.

### TECHNICAL FIELD

The present disclosure relates to a semiconductor device and a manufacturing method of a semiconductor device.

### BACKGROUND

Generally, electrodes of semiconductor devices are composed of metals such as aluminum.

### SUMMARY

A semiconductor device according to one aspect of the present disclosure includes an electrode. The electrode includes a copper electrode layer. The copper electrode layer may contain an element that, when combined with hydrogen, forms a compound with a vapor pressure higher than atmospheric pressure.

### BRIEF DESCRIPTION OF DRAWINGS

Objects, features and advantages of the present disclosure will become apparent from the following detailed description made with reference to the accompanying drawings. In the drawings:

FIG. 1 is a schematic diagram of a semiconductor device according to a first embodiment;

FIG. 2 is an enlarged perspective view of the semiconductor device in region II in FIG. 1;

FIG. 3 is a diagram for explaining a manufacturing method of the semiconductor device according to the first embodiment;

FIG. 4 is a diagram for explaining the manufacturing method of the semiconductor device according to the first embodiment;

FIG. 5 is a diagram for explaining the manufacturing method of the semiconductor device according to the first embodiment;

FIG. 6 is a diagram for explaining the manufacturing method of the semiconductor device according to the first embodiment;

FIG. 7 is a diagram for explaining the manufacturing method of the semiconductor device according to the first embodiment;

FIG. 8 is a diagram for explaining the manufacturing method of the semiconductor device according to the first embodiment; and

FIG. 9 is a diagram for explaining a manufacturing method of a semiconductor device according to a second embodiment.

### DETAILED DESCRIPTION

In some cases, an electrode layer of a semiconductor device is composed of copper. When a copper electrode layer is used as the electrode layer of the semiconductor device, the heat dissipation performance of the semiconductor device can be improved. The copper electrode layer contains a small amount of oxide (for example, copper oxide) inside. In addition, during use of the semiconductor device, hydrogen enters the interior of the copper electrode layer. When hydrogen enters the interior of the copper electrode layer, the oxide reacts with the hydrogen to generate water. When the generated water changes into steam, the resulting volumetric expansion causes voids to form inside the copper electrode layer. This phenomenon is called hydrogen embrittlement. When hydrogen embrittlement occurs, issues such as a decrease in the strength of the electrode and a reduction in the thermal conductivity of the electrode arise.

A semiconductor device according to one aspect of the present disclosure includes an electrode. The electrode includes a copper electrode layer. The copper electrode layer contains an element that, when combined with hydrogen, forms a compound with a vapor pressure higher than atmospheric pressure.

In the above semiconductor device, when hydrogen enters the interior of the copper electrode layer during use, the hydrogen reacts with the element contained in the copper electrode layer to form the compound. Since the vapor pressure of the compound is higher than atmospheric pressure, the compound is in a gaseous state. Therefore, even if the compound is generated, no phase change from liquid to gas occurs, and no volumetric expansion of the compound occurs. In addition, since the hydrogen that has entered the copper electrode layer reacts with the element, the reaction between oxides contained inside the copper electrode layer and hydrogen is suppressed. As a result, the generation of water is suppressed, so volumetric expansion due to vaporization of water does not occur. Therefore, the formation of voids inside the copper electrode layer is less likely, and hydrogen embrittlement of the copper electrode layer can be suppressed.

In one example of the semiconductor device disclosed in the present disclosure, the element may be fluorine or chlorine.

Fluorine and chlorine form compounds with hydrogen that have a higher vapor pressure than atmospheric pressure. Therefore, when the copper electrode layer contains fluorine or chlorine, hydrogen embrittlement of the copper electrode layer can be suppressed.

In one example of the semiconductor device disclosed in the present disclosure, a concentration of the element may be 1×10¹⁶ atoms/cm³ or more.

One example of the semiconductor device disclosed in the present disclosure may include a semiconductor substrate. The electrode may be in contact with the semiconductor substrate. The copper electrode layer may have a main surface on a side of the copper electrode layer located opposite to the semiconductor substrate. A concentration of the element in a surface portion of the copper electrode layer that is located adjacent to the main surface may be higher than a concentration of the element in a portion of the copper electrode layer that is located deeper than the surface portion from the main surface.

According to this configuration, during use of the semiconductor device, the element and hydrogen readily react in the surface portion adjacent to the main surface. Therefore, in the copper electrode layer, the penetration of hydrogen into the portion deeper than the surface portion can be suppressed.

One example of the semiconductor device disclosed in the present disclosure may further include a polyimide film in contact with the copper electrode layer.

The polyimide film contains a large amount of hydrogen as an impurity. According to this configuration, hydrogen embrittlement of the copper electrode layer caused by hydrogen generated from the polyimide film can be suppressed.

One example of a manufacturing method of a semiconductor device disclosed in the present disclosure may include forming an electrode including a copper electrode layer on a semiconductor substrate, and exposing the copper electrode layer to CF₄ gas while the copper electrode layer is in an exposed state.

According to this configuration, it is possible to form a copper electrode layer containing fluorine. Therefore, hydrogen embrittlement of the copper electrode layer can be suppressed.

One example of a manufacturing method of a semiconductor device disclosed in the present disclosure may include forming an electrode including a copper electrode layer on a semiconductor substrate, and exposing the copper electrode layer to BCl₃ gas while the copper electrode layer is in an exposed state.

According to this configuration, it is possible to form a copper electrode layer containing chlorine. Therefore, hydrogen embrittlement of the copper electrode layer can be suppressed.

### First Embodiment

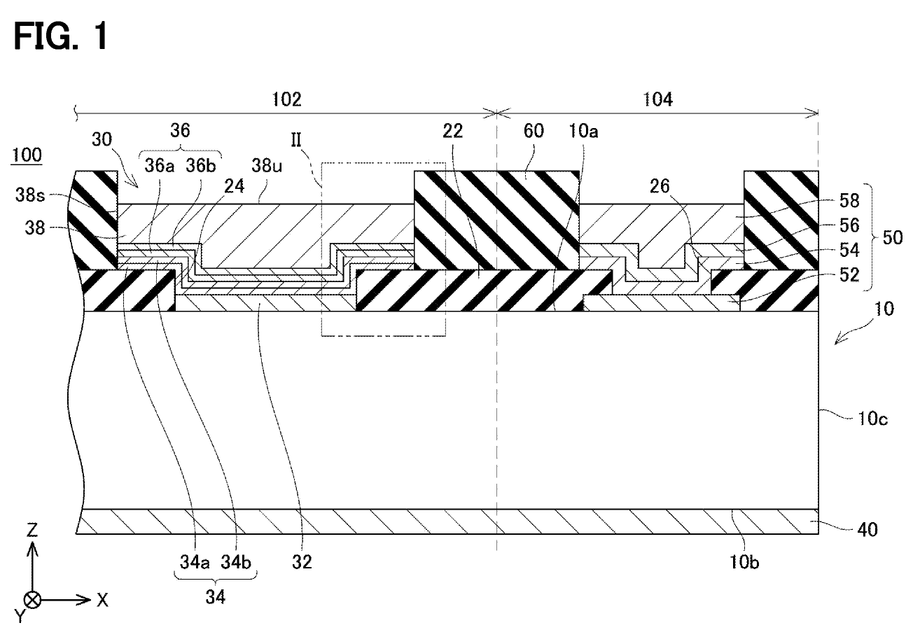

A semiconductor device 100 shown in FIG. 1 includes a semiconductor substrate 10. The semiconductor substrate 10 is composed of SiC. The semiconductor substrate 10 may also be composed of other semiconductor materials such as silicon or gallium nitride. Hereinafter, a thickness direction of the semiconductor substrate 10 will be referred to as a z-direction, a direction parallel to an upper surface 10a of the semiconductor substrate 10 will be referred to as an x-direction, and a direction parallel to the upper surface 10a and perpendicular to the x-direction will be referred to as a y-direction.

The semiconductor substrate 10 has an element region 102 and an outer peripheral region 104. A metal oxide semiconductor field effect transistor (MOSFET) is provided in the element region 102. The outer peripheral region 104 is disposed between an outer peripheral surface 10c of the semiconductor substrate 10 and the element region 102.

The semiconductor device 100 includes an interlayer insulating film 22. The interlayer insulating film 22 is in contact with the upper surface 10a of the semiconductor substrate 10 over a region spanning both the element region 102 and the outer peripheral region 104. In the element region 102, a contact hole 24 is provided in the interlayer insulating film 22. In the outer peripheral region 104, a contact hole 26 is provided in the interlayer insulating film 22. The interlayer insulating film 22 is made of a silicon oxide material with high fluidity, such as boron phosphosilicate glass (BPSG).

The semiconductor device 100 includes an upper electrode 30. The upper electrode 30 is disposed in the element region 102. The upper electrode 30 is in contact with the upper surface 10a of the semiconductor substrate 10 within the contact hole 24. The upper electrode 30 covers an upper surface of the interlayer insulating film 22 around the contact hole 24. Within the contact hole 24, the upper electrode 30 is in ohmic contact with the semiconductor substrate 10. The upper electrode 30 includes a silicide layer 32, a barrier metal layer 34, a seed layer 36, and a copper electrode layer 38.

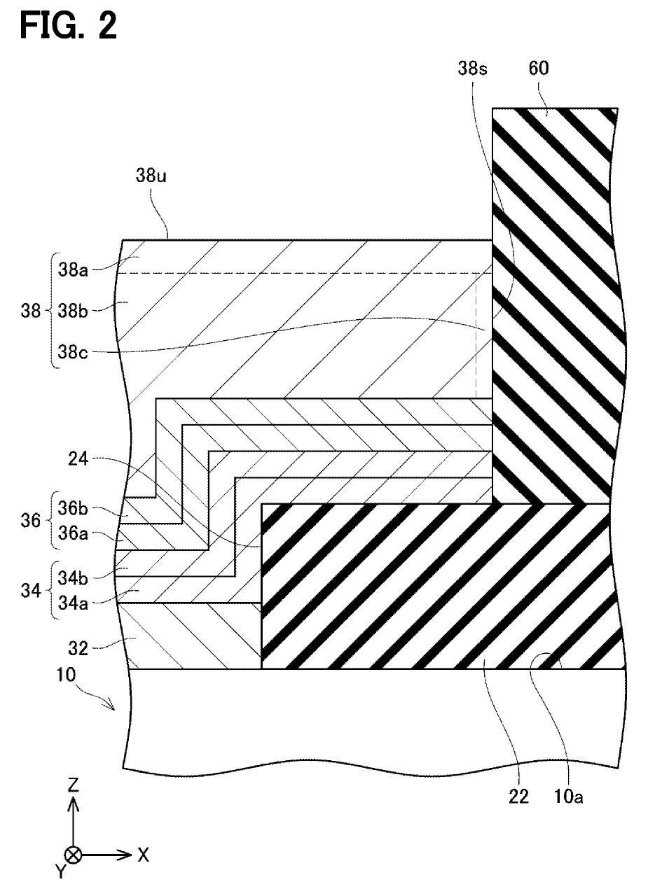

As shown in FIG. 1 and FIG. 2, the silicide layer 32 is provided within the contact hole 24. The silicide layer 32 is composed of silicide (for example, titanium silicide). The silicide layer 32 covers the entire region of the upper surface 10a of the semiconductor substrate 10 within the contact hole 24.

As shown in FIG. 1 and FIG. 2, the barrier metal layer 34 includes a first barrier metal layer 34a and a second barrier metal layer 34b. The first barrier metal layer 34a covers the entire region of an upper surface of the silicide layer 32 within the contact hole 24. The first barrier metal layer 34a covers the upper surface of the interlayer insulating film 22 around the contact hole 24. The first barrier metal layer 34a is composed of, for example, titanium. The second barrier metal layer 34b covers the entire region of a surface of the first barrier metal layer 34a. The second barrier metal layer 34b is composed of, for example, titanium nitride.

As shown in FIG. 1 and FIG. 2, the seed layer 36 includes a first seed layer 36a and a second seed layer 36b. The first seed layer 36a covers the entire region of a surface of the second barrier metal layer 34b. The first seed layer 36a is composed of, for example, titanium. The second seed layer 36b covers the entire region of a surface of the first seed layer 36a. The second seed layer 36b is composed of, for example, copper.

As shown in FIG. 1 and FIG. 2, the copper electrode layer 38 covers the entire region of a surface of the second seed layer 36b. The copper electrode layer 38 is disposed above the contact hole 24 and the interlayer insulating film 22 surrounding the contact hole 24. A thickness (that is, a dimension in the z-direction) of the copper electrode layer 38 is greater than a thickness of each of the barrier metal layer 34 and the seed layer 36. The copper electrode layer 38 contains fluorine (F).

An upper surface 38u of the copper electrode layer 38 is a main surface located on a side of the copper electrode layer 38 located opposite to the semiconductor substrate 10. The copper electrode layer 38 has a surface portion 38a located adjacent to the upper surface 38u, a side portion 38c located adjacent to the side surface 38s of the copper electrode layer 38, and a lower portion 38b.

The surface portion 38a is provided in a portion that includes the upper surface 38u of the copper electrode layer 38. For example, a thickness of the surface portion 38a (that is, a dimension in the z-direction) is 60 nm. Fluorine is contained in the surface portion 38a. The fluorine concentration in the surface portion 38a is, for example, 1×10¹⁶ atoms/cm³ or more. In addition, the fluorine concentration in the surface portion 38a is, for example, 1×10²¹ atoms/cm³ or less.

The side portion 38c is provided in a region that includes the side surface 38s of the copper electrode layer 38. A thickness of the side portion 38c (that is, a dimension in the x-direction) is smaller than the thickness of the surface portion 38a. Fluorine is contained in the side portion 38c.

The lower portion 38b is located below the surface portion 38a (that is, in a region deeper than the surface portion 38a from the upper surface 30u) and is provided in a portion that is not exposed to the side surface 38s. The lower portion 38b is a layer having a lower fluorine concentration than the surface portion 38a and the side portion 38c. Accordingly, in the lower portion 38b, the purity of copper is higher than in the surface portion 38a and the side portion 38c.

The semiconductor device 100 includes a signal electrode pad 50. The signal electrode pad 50 is provided within the outer peripheral region 104. The signal electrode pad 50 is provided within the contact hole 26 and in a region surrounding the contact hole 26. The signal electrode pad 50 includes a polysilicon film 52, a barrier metal layer 54, a seed layer 56, and a copper electrode layer 58. The polysilicon film 52 covers the upper surface 10a of the semiconductor substrate 10 within the contact hole 26. The barrier metal layer 54 covers the entire region of an upper surface of the polysilicon film 52. Additionally, the barrier metal layer 54 covers the upper surface of the interlayer insulating film 22 around the contact hole 26. Each of the barrier metal layer 54, the seed layer 56, and the copper electrode layer 58 has the same structure as the barrier metal layer 34, the seed layer 36, and the copper electrode layer 38, respectively.

The semiconductor device 100 includes a polyimide film 60. The polyimide film 60 is disposed in the element region 102 and the outer peripheral region 104. The polyimide film 60 covers the upper surface of the interlayer insulating film 22. The polyimide film 60 is in contact with the side surfaces of the upper electrode 30 and the signal electrode pad 50. That is, the polyimide film 60 is in contact with the side surface 38s of the copper electrode layer 38. The upper surface 38u of the copper electrode layer 38 and the upper surface of the copper electrode layer 58 are exposed from the polyimide film 60.

The semiconductor device 100 includes a lower electrode 40. The lower electrode 40 is in contact with the entire region of a lower surface 10b of the semiconductor substrate 10.

During use of the semiconductor device 100, a signal terminal is connected to the signal electrode pad 50, and a signal is applied to the signal electrode pad 50 via the signal terminal. In addition, an external terminal is connected to the upper electrode 30 (that is, the copper electrode layer 38), another external terminal is connected to the lower electrode 40, and a current flows between the upper electrode 30 and the lower electrode 40. In addition, heat generated in the semiconductor device 100 is dissipated to the outside via the upper electrode 30 and the lower electrode 40. That is, the upper electrode 30 and the lower electrode 40 also function as heat dissipation paths.

During use of the semiconductor device 100, hydrogen released from the polyimide film 60 or hydrogen that has diffused into the semiconductor device 100 from the atmosphere may enter the copper electrode layer 38. Oxides (for example, copper oxide) are present as impurities within the copper electrode layer 38. If the copper electrode layer 38 does not contain fluorine, the copper oxide within the copper electrode layer 38 reacts with hydrogen, resulting in the generation of water within the copper electrode layer 38. When the generated water turns into steam, the resulting volumetric expansion causes voids to form within the copper electrode layer 38. That is, hydrogen embrittlement occurs in the copper electrode layer 38. In contrast, in the present embodiment, since the copper electrode layer 38 contains fluorine, the hydrogen that enters the copper electrode layer 38 reacts with the fluorine, generating hydrogen fluoride (HF). Hydrogen fluoride is a compound with a vapor pressure higher than atmospheric pressure and exists as a gas. Therefore, even if the fluorine in the copper electrode layer 38 is converted to hydrogen fluoride, no phase change from liquid to gas occurs, and thus no volumetric expansion takes place. As a result, it becomes difficult for voids to form inside the copper electrode layer 38, thereby suppressing hydrogen embrittlement of the copper electrode layer 38. In particular, in the present embodiment, since the surface portion 38a and the side portion 38c of the copper electrode layer 38 contain fluorine, the fluorine contained in the surface portion 38a and the side portion 38c reacts with the hydrogen that has entered the copper electrode layer 38. Therefore, it becomes difficult for hydrogen to penetrate into the interior (that is, the lower portion 38b) of the copper electrode layer 38. As a result, hydrogen embrittlement in the lower portion 38b can be effectively suppressed. Thus, in the present embodiment, since hydrogen embrittlement can be suppressed, deterioration of the thermal conductivity and electrical conductivity of the copper electrode layer 38 can also be suppressed.

In addition, since the fluorine concentration in the lower portion 38b is low, the copper purity of the lower portion 38b is high. Therefore, in the upper electrode 30, high thermal conductivity and electrical conductivity can be achieved.

Since hydrogen is released from the polyimide film, hydrogen embrittlement of the copper electrode layer is likely to occur in semiconductor devices having a polyimide film. In contrast, as in the present embodiment, when the copper electrode layer 38 contains fluorine, even if the polyimide film 60 is in contact with the copper electrode layer 38, hydrogen embrittlement of the copper electrode layer 38 can be suppressed. Thus, in semiconductor devices having a polyimide film, employing a copper electrode layer containing fluorine is more advantageous.

In the above embodiment, the lower portion 38b has a lower fluorine concentration than the surface portion 38a. However, the lower portion 38b may have a fluorine concentration similar to that of the surface portion 38a. Even with this configuration, hydrogen embrittlement can be suppressed.

Since the copper electrode layer 58 has a structure similar to that of the copper electrode layer 38, the copper electrode layer 58 provides effects similar to those of the copper electrode layer 38. Therefore, hydrogen embrittlement of the copper electrode layer 58 of the signal electrode pad 50 can be suppressed.

Next, a manufacturing method of the first embodiment will be described. Hereinafter, among manufacturing processes of the semiconductor device 100, processes for forming the upper electrode 30 and the polyimide film 60 will be described.

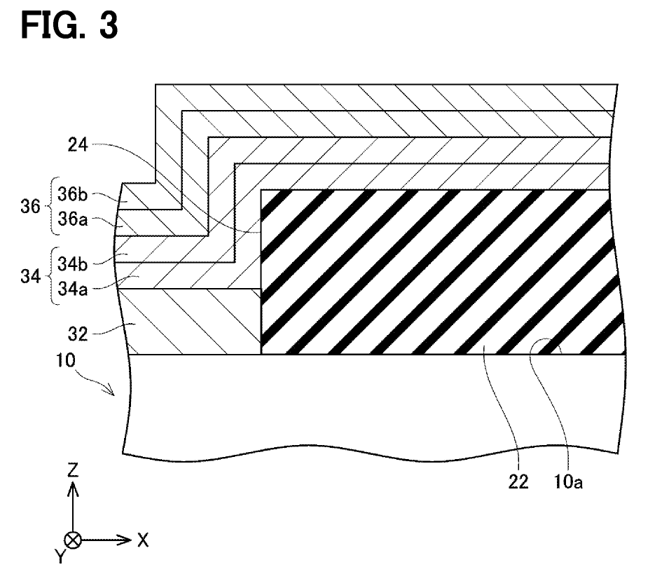

First, as shown in FIG. 3, the interlayer insulating film 22 is formed on the upper surface 10a of the semiconductor substrate 10. Next, the silicide layer 32 is formed inside the contact hole 24. Next, the barrier metal layer 34 and the seed layer 36 are formed so as to cover the upper surface of the silicide layer 32 and the upper surface of the interlayer insulating film 22.

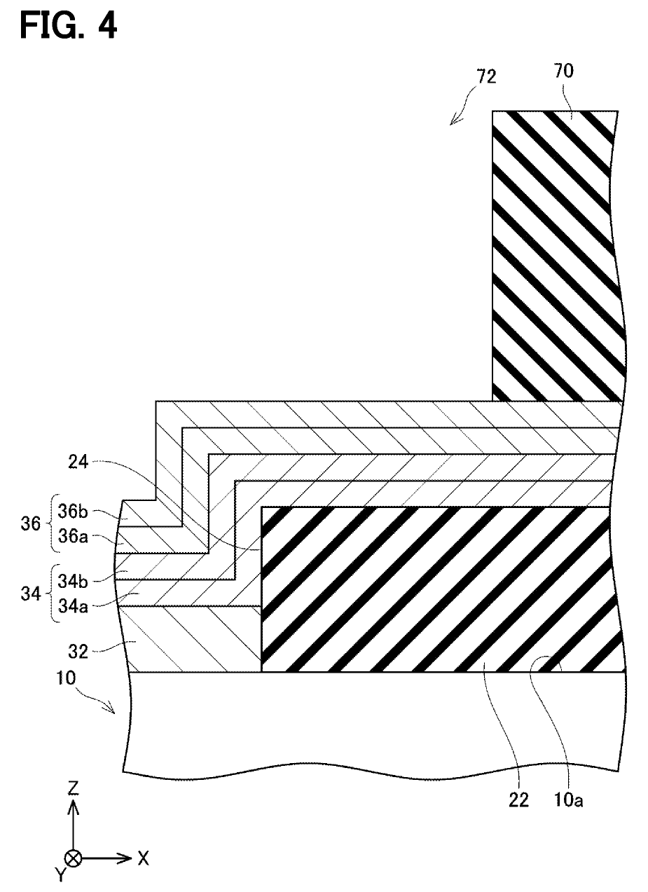

Next, as shown in FIG. 4, a resist mask 70 having an opening portion 72 is formed on the seed layer 36. The opening portion 72 is formed above the contact hole 24. Within the opening portion 72, the contact hole 24 and its peripheral region are located.

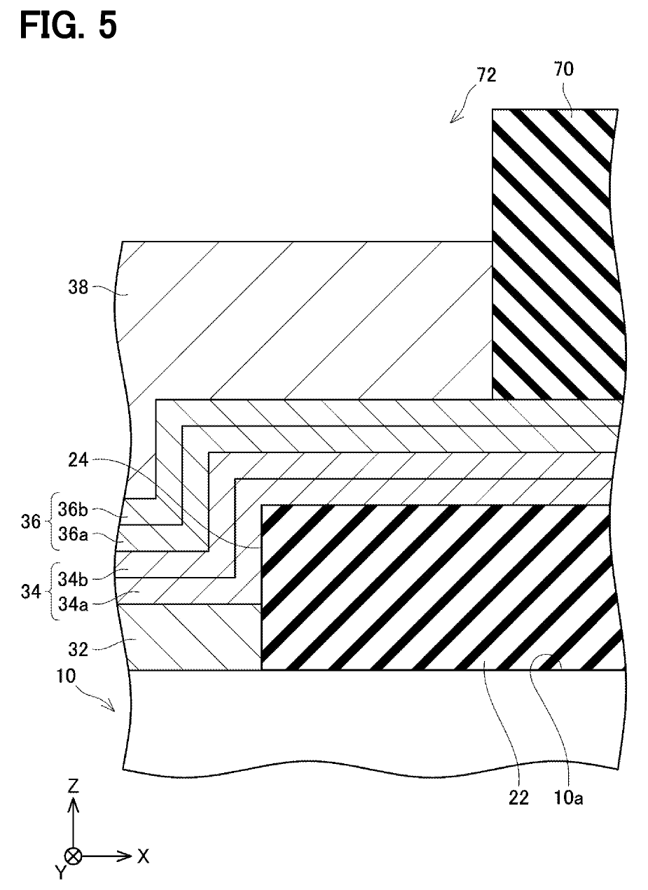

Next, as shown in FIG. 5, for example, using plating technology, the copper electrode layer 38 is formed on the seed layer 36 within the opening portion 72. Thereafter, the resist mask 70 is removed.

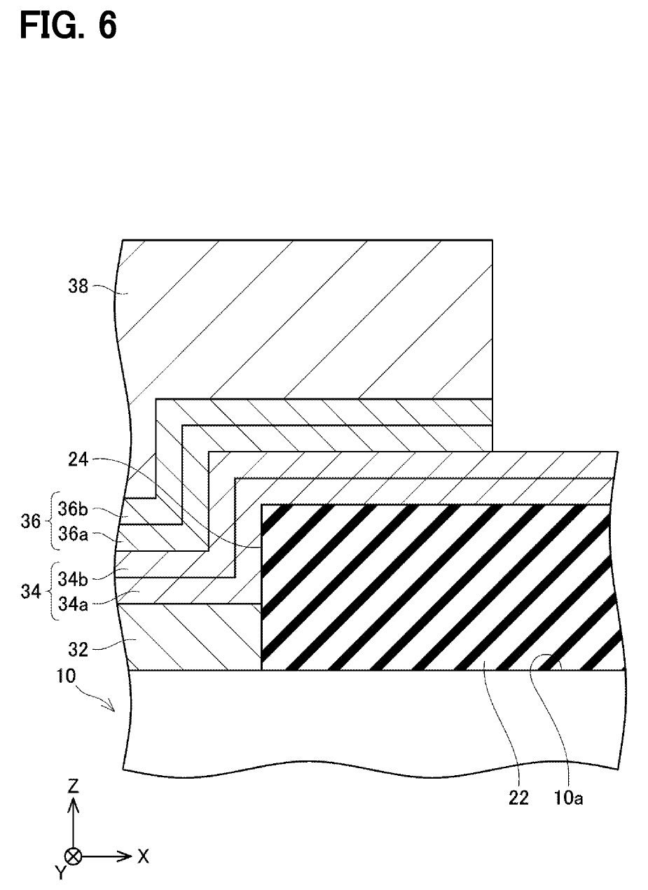

Next, as shown in FIG. 6, the seed layer 36 is removed by wet etching. It should be noted that the copper electrode layer 38 is also etched during the etching of the seed layer 36. However, since the copper electrode layer 38 is sufficiently thicker than the seed layer 36, the reduction rate in the thickness of the copper electrode layer 38 is extremely small.

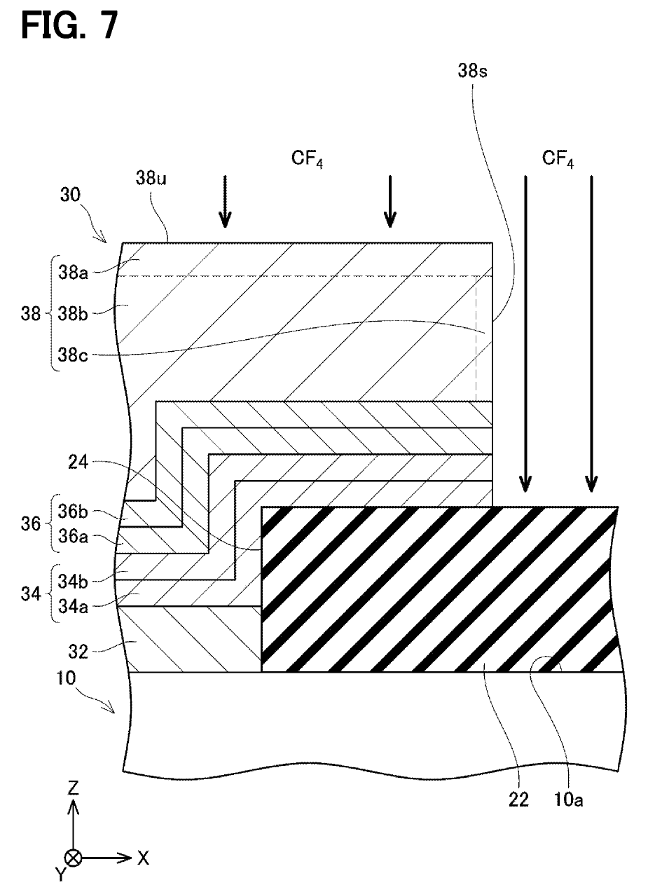

Next, as shown in FIG. 7, the barrier metal layer 34 is etched by reactive ion etching using CF₄ gas. With this process, a portion of the barrier metal layer 34 exposed from the copper electrode layer 38 is removed. At this time, since the upper surface 38u of the copper electrode layer 38 is exposed, the upper surface 38u is exposed to the CF₄ gas. Therefore, fluorine contained in the CF₄ gas diffuses into the surface portion 38a of the copper electrode layer 38. In addition, since the side surface 38s of the copper electrode layer 38 is exposed, the side surface 38s is also exposed to the CF₄ gas. Therefore, the fluorine contained in the CF₄ gas diffuses into the side portion 38c of the copper electrode layer 38. Accordingly, the fluorine concentration increases in the surface portion 38a and the side portion 38c. In the lower portion 38b, the fluorine concentration hardly increases. In the lower portion 38b, the fluorine concentration is below the detection limit. It should be noted that although the copper electrode layer 38 is also etched during the etching of the barrier metal layer 34, the copper electrode layer 38 is sufficiently thicker than the barrier metal layer 34, so the rate of decrease in the thickness of the copper electrode layer 38 is extremely small.

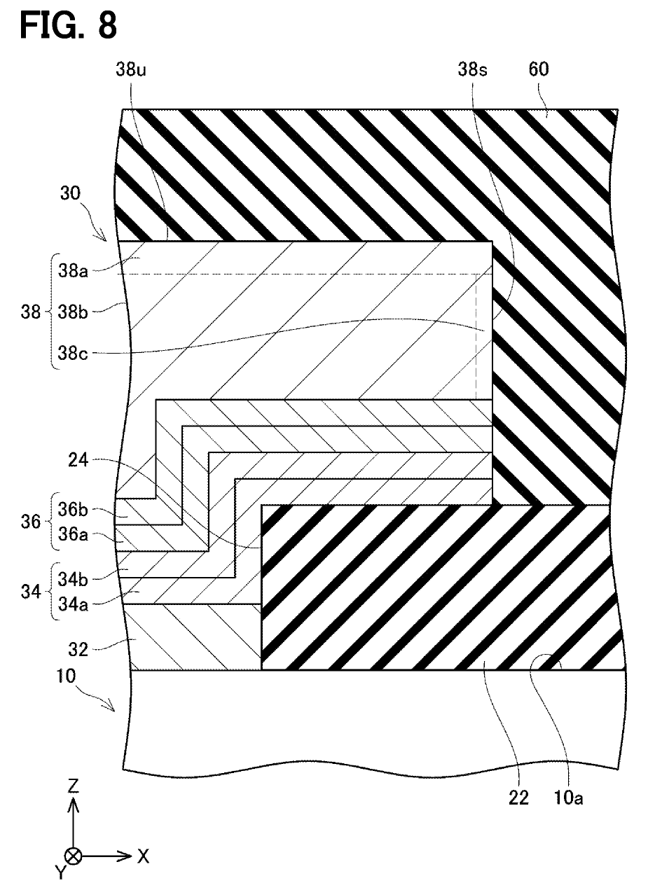

Next, as shown in FIG. 8, the polyimide film 60 is formed so as to cover the interlayer insulating film 22 and the upper electrode 30. At this time, the polyimide film 60 comes into contact with the side surface 38s and the upper surface 38u of the copper electrode layer 38. During the process of forming the polyimide film 60, hydrogen diffuses from the polyimide film 60 into the copper electrode layer 38. However, since the copper electrode layer 38 contains fluorine, hydrogen embrittlement in the copper electrode layer 38 is suppressed.

Thereafter, as shown in FIG. 2, the polyimide film 60 above the copper electrode layer 38 is removed, exposing the upper surface 38u of the copper electrode layer 38. As a result, the semiconductor device 100 shown in FIG. 1 is completed.

In the manufacturing method of the first embodiment described above, it is possible to form the copper electrode layer 38 containing fluorine. Therefore, during the use of the semiconductor device 100, hydrogen embrittlement of the copper electrode layer 38 can be suppressed.

### Second Embodiment

In a semiconductor device of a second embodiment, copper electrode layers 38 and 58 contain chlorine (Cl) instead of fluorine. The other configurations in the second embodiment are the same as those in the first embodiment. Chlorine reacts with hydrogen to produce hydrogen chloride (HCl). The vapor pressure of hydrogen chloride is higher than atmospheric pressure. Therefore, as in the case of fluorine, hydrogen embrittlement of the copper electrode layer 38 is suppressed.

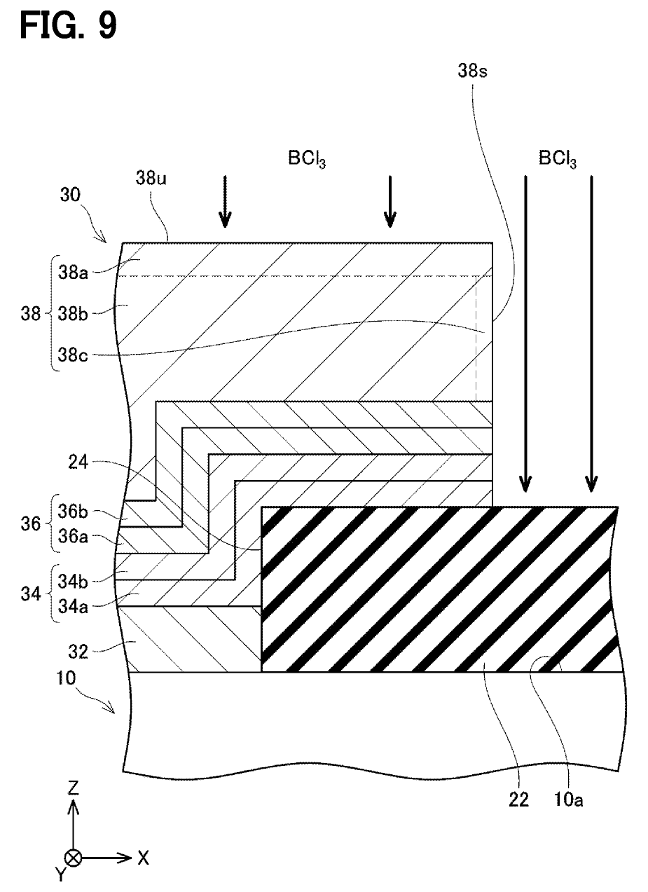

Next, a manufacturing method of the second embodiment will be described. In the manufacturing method of the second embodiment, processing is carried out in the same manner as in the manufacturing method of the first embodiment up to the state shown in FIG. 6. Next, as shown in FIG. 9, a portion of the barrier metal layer 34 exposed from the copper electrode layer 38 is removed by reactive ion etching using BCl₃ gas. At this time, chlorine diffuses into the surface portion 38a and the side portion 38c of the copper electrode layer 38. As a result, the copper electrode layer 38 containing chlorine is obtained in the surface portion 38a and the side portion 38c. Thereafter, as in the first embodiment, the semiconductor device is completed by forming the polyimide film 60.

Although the embodiments have been described in detail above, these are merely examples and do not limit the scope of present disclosure. The technology described in the claims includes various modifications and variations of the specific examples illustrated above. The technical elements described in the present specification or the drawings exhibit technical usefulness alone or in various combinations, and are not limited to the combinations described in the claims at the time of filing. In addition, the techniques illustrated in the present specification or drawings achieve a plurality of objectives at the same time, and achieving one of the objectives itself has technical usefulness.

What is claimed is:

1. A semiconductor device comprising:
an electrode including a copper electrode layer, wherein
the copper electrode layer contains an element that, when combined with hydrogen, forms a compound with a vapor pressure higher than atmospheric pressure.

2. The semiconductor device according to claim 1, wherein
the element is fluorine or chlorine.

3. The semiconductor device according to claim 1, wherein
a concentration of the element is 1×10¹⁶ atoms/cm³ or more.

4. The semiconductor device according to claim 1, further comprising:
a semiconductor substrate, wherein
the electrode is in contact with the semiconductor substrate,
the copper electrode layer has a main surface on a side of the copper electrode layer that is located opposite to the semiconductor substrate, and
a concentration of the element in a surface portion of the copper electrode layer that is located adjacent to the main surface is higher than a concentration of the element in a portion of the copper electrode layer that is located deeper than the surface portion from the main surface.

5. The semiconductor device according to claim 1, further comprising
a polyimide film in contact with the copper electrode layer.

6. A manufacturing method of a semiconductor device, comprising:
forming an electrode including a copper electrode layer on a semiconductor substrate; and
exposing the copper electrode layer to CF₄ gas while the copper electrode layer is in an exposed state.

7. A manufacturing method of a semiconductor device, comprising:
forming an electrode including a copper electrode layer on a semiconductor substrate; and
exposing the copper electrode layer to BCl₃ gas while the copper electrode layer is in an exposed state.
